(19) United States
(12) Patent Application Publication
(10) Pub. No.: US 2020/0073224 A1
(43) Pub. Date: Mar. 5, 2020

(54) MASK AND METHOD FOR MANUFACTURING THE SAME AND METHOD FOR PATTERNING A LAYER

(71) Applicant: TAIWAN SEMICONDUCTOR MANUFACTURING COMPANY LTD., HSINCHU (TW)

(72) Inventors: CHUN-LANG CHEN, TAINAN COUNTY (TW); JHENG-YUAN CHEN, HSINCHU (TW); CHIH-CHIANG TU, TAOYUAN (TW); SHIH-HAO YANG, TAINAN CITY (TW)

(21) Appl. No.: 16/455,257

(22) Filed: Jun. 27, 2019

Related U.S. Application Data
(60) Provisional application No. 62/724,878, filed on Aug. 30, 2018.

(51) Int. Cl. G03F 1/22; H01L 21/027; G03F 1/52; G03F 1/54; G03F 7/20; G03F 7/26

(52) U.S. Cl. CPC G03F 1/22; H01L 21/0274; G03F 1/52; H01L 21/31144; G03F 7/2004; G03F 7/26; G03F 1/54

(57) ABSTRACT

A mask for reflecting an electromagnetic radiation includes a substrate, a reflective multi-layered stack over a surface of the substrate, a metal capping layer over the reflective multi-layered stack, a metal silicide buffer layer over the metal capping layer, and an optical absorber pattern over the metal silicide buffer layer.

### PRIORITY CLAIM AND CROSS-REFERENCE

This application claims priority of U.S. provisional application Ser. No. 62/724,878 filed on Aug. 30, 2018, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. This scaling down process generally provides benefits by increasing production efficiency and lowering related manufacturing costs. Such scaling down, however, has also increased the complexity of IC manufacturing. To fabricate extremely small features, high resolution lithography techniques such as extreme ultraviolet (EUV) lithography, X-Ray lithography, ion beam projection lithography and electron-beam projection lithography are developed.

Among the high resolution lithography techniques, EUV lithography, for example, employs scanners using light in the EUV region, having a wavelength of lower than about 100 nm. However, many condensed materials absorb at the EUV wavelength, so a mask for EUV lithography is reflective, and the desired pattern on an EUV mask is defined by selectively removing portions of an optical absorber layer (also referred to as EUV mask optical absorber) to uncover portions of an underlying reflective multilayer (also referred to as ML) configured as a mirror and formed on a substrate.

Selective removal of portions of the optical absorber layer generally involves etching trenches through portions of the optical absorber material using a mask. The reflective multilayer, however, is susceptible to surface damage during removal of portions of the optical absorber layer as well as removal of the mask, which leads to EUV reflectivity loss and structure degradation.

### BRIEF DESCRIPTION OF THE DRAWINGS

Aspects of the embodiments of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 is a schematic view diagram illustrating an electromagnetic radiation generation apparatus, in accordance with some embodiments of the present disclosure.

FIG. 2 is a flow chart illustrating a method for manufacturing a mask, in accordance with various aspects of one or more embodiments of the present disclosure.

FIG. 3A, FIG. 3B, FIG. 3C, FIG. 3D, FIG. 3E and FIG. 3F are schematic views at one or more of various operations of manufacturing a mask in accordance with one or more embodiments of the present disclosure.

FIG. 4 is a simulation result showing reflection of a stack of a capping layer and a buffer layer.

FIG. 5 is a schematic view diagram illustrating a mask, in accordance with some embodiments of the present disclosure.

FIG. 6 is a schematic view diagram illustrating a mask, in accordance with some embodiments of the present disclosure.

FIG. 7 is a flow chart illustrating a method of patterning a layer using a mask, in accordance with various aspects of one or more embodiments of the present disclosure.

FIG. 8A, FIG. 8B and FIG. 8C are schematic views at one or more of various operations of patterning a layer using a mask in accordance with one or more embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

In one or more embodiments of the present disclosure, a mask for reflecting an electromagnetic radiation and fabrication method thereof are provided. The mask utilizes a buffer layer to cover a capping layer. The buffer layer and the capping layer are similar in optical characteristics but different in etch rate with respect to an etchant for patterning overlying optical absorber layer. The etch rate of the buffer layer is lower than the etch rate of the optical absorber layer with respect to the same etchant when patterning the optical absorber layer. The buffer layer can protect the capping layer and underlying reflective multi-layered stack, while the optical performance of the mask may be maintained.

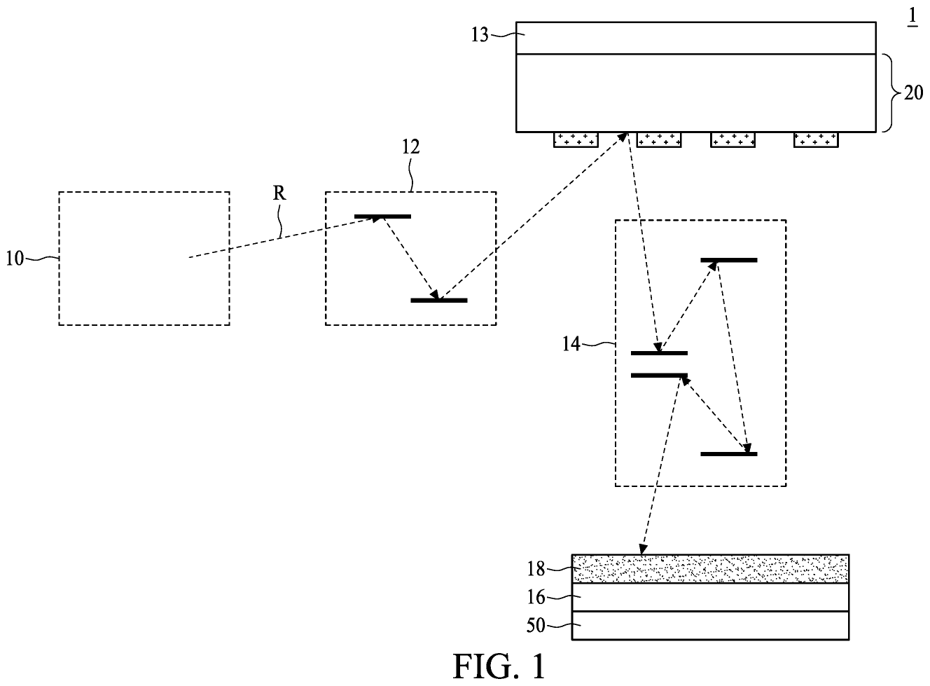

Refer to FIG. 1. FIG. 1 is a schematic view diagram illustrating an electromagnetic radiation generation apparatus, in accordance with some embodiments of the present disclosure. The extreme ultraviolet (EUV) lithography system electromagnetic radiation generation apparatus 1 is configured to generate an electromagnetic radiation R. The electromagnetic radiation generation apparatus 1 may be, but is not limited to, operable to perform lithography exposing operation with EUV radiation. The EUV lithography system is configured to radiate an EUV radiation on a photoresist layer having a material sensitive to the EUV radiation. The electromagnetic radiation generation apparatus 1 includes a radiation source 10 configured to generate an EUV radiation, such as an EUV radiation having a wavelength ranging between about 1 nm and about 100 nm. In some embodiments, the radiation source 10 generates an EUV radiation with a wavelength centered at about 13.5 nm, but is not limited thereto.

The electromagnetic radiation generation apparatus 1 may further include an illuminator 12. The illuminator 12 may include various refractive optic components such as a single lens or a lens system having multiple lenses, or alternatively reflective optics such as a single mirror or a mirror system having multiple mirrors, to direct the electromagnetic radiation R from the radiation source 10 to a mask 20 (also referred to a reticle or a photomask) mounted on a mask carrier 13. In some embodiments, the mask carrier 13 may include an electrostatic chuck (E-chuck) to secure the mask 20. In some embodiments, the electromagnetic radiation generation apparatus 1 is an EUV lithography system, and the mask 20 is a reflective mask. The mask 20 may include a substrate formed by a low thermal expansion material (LTEM) such as quartz, titanium oxide doped silicon oxide, or other suitable materials. The mask 20 may further include a reflective multi-layered stack disposed on the substrate. The reflective multi-layered stack may include a plurality of film pairs, such as molybdenum-silicon (Mo/Si) film pairs (e.g., a layer of molybdenum and a layer of silicon stacked to each other in each film pair). In some other embodiments, the reflective multi-layered stack may include molybdenum-beryllium (Mo/Be) film pairs, or other suitable materials that are configurable to highly reflect the EUV radiation. The mask 20 may further include other layers such as a capping layer, a buffer layer and an optical absorption pattern, which will be detailed in following paragraphs.

The electromagnetic radiation generation apparatus 1 may also include a projection optical unit 14 for transferring the pattern of the mask 20 to a photoresist layer 18 to be patterned disposed on a wafer 50. The photoresist layer 18 includes a material sensitive to the electromagnetic radiation R. The wafer 50 may be mounted on a substrate carrier (not shown). In some embodiments, the projection optical unit 14 may include reflective optics. The electromagnetic radiation R directed from the mask 20 carries the image of the pattern defined on the mask 20, and is conveyed to the photoresist layer 18 by the projection optical unit 14. In some embodiments, the photoresist layer 18 exposed to the electromagnetic radiation R can be patterned by exposure and development to form a photoresist pattern. In some embodiments, the photoresist pattern may be then used as an etching mask to define the pattern of underlying layer(s) 16.

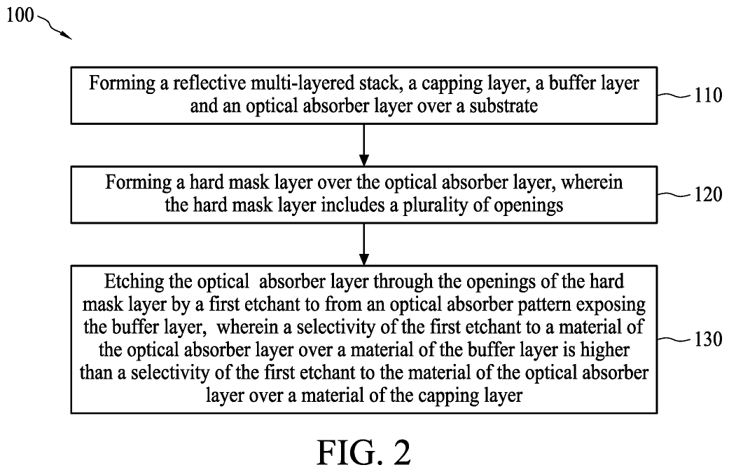

Refer to FIG. 2. FIG. 2 is a flow chart illustrating a method for manufacturing a mask, in accordance with various aspects of one or more embodiments of the present disclosure. The method 100 begins with operation 110 in which a reflective multi-layered stack, a capping layer, a buffer layer and an optical absorber layer are formed over a substrate. The method 100 proceeds with operation 120 in which a hard mask layer is formed over the optical absorber layer, wherein the hard mask layer includes a plurality of openings. The method 100 proceeds with operation 130 in which the optical absorber layer is etched through the openings of the hard mask layer by a first etchant to from an optical absorber pattern exposing the buffer layer, wherein a selectivity of the first etchant to a material of the optical absorber pattern over a material of the buffer layer is higher than a selectivity of the first etchant to the material of the optical absorber pattern over a material of the capping layer.

The method 100 is merely an example, and is not intended to limit the present disclosure beyond what is explicitly recited in the claims. Additional operations can be provided before, during, and after the method 100, and some operations described can be replaced, eliminated, or moved around for additional embodiments of the method.

In some embodiments, the method may further includes an operation in which the hard mask layer is etched by a second etchant and removed from the optical absorber pattern, wherein a selectivity of the second etchant to a material of the hard mask layer over the material of the buffer layer is higher than a selectivity of the second etchant to the material of the hard mask layer over the material of the capping layer. In some embodiments, the method may further include an operation in which the characteristics of the material of the buffer layer are matched with that of the material of the capping layer.

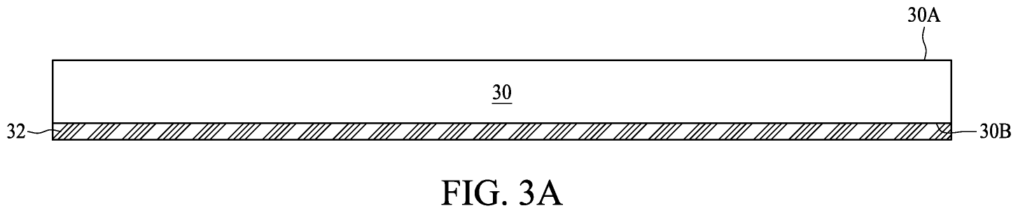

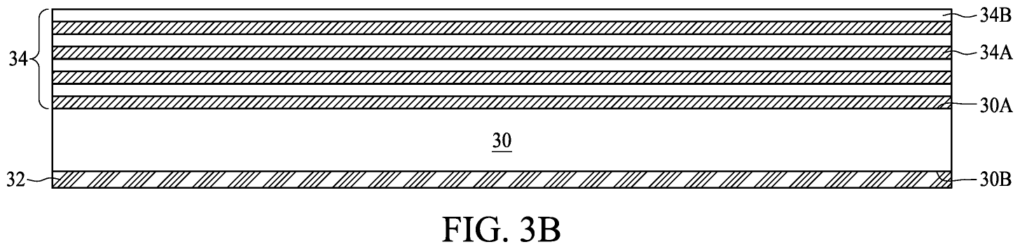

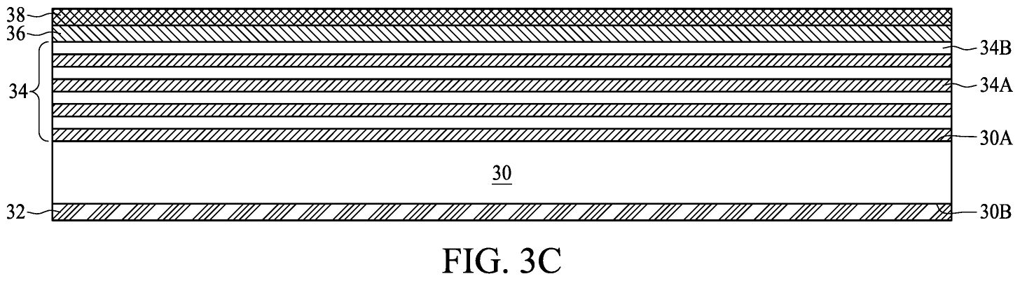

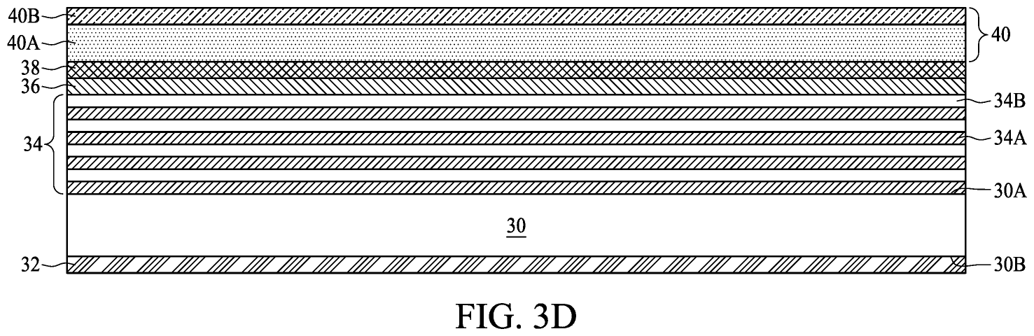

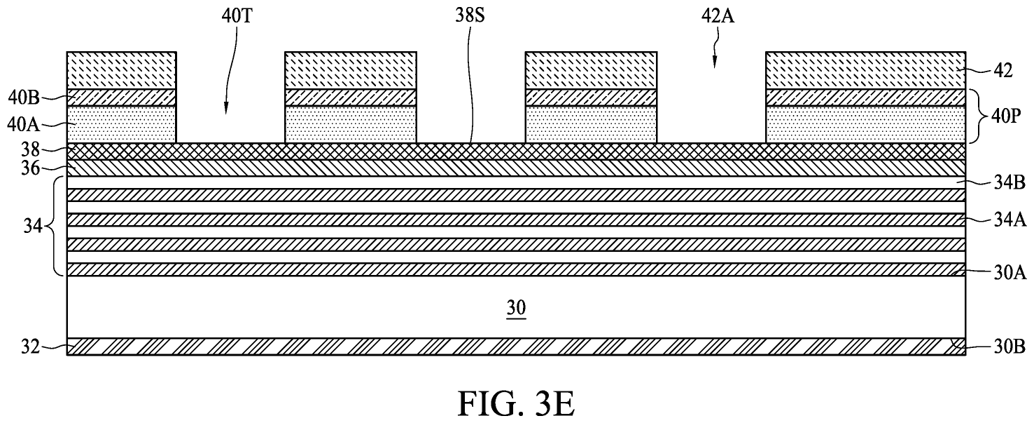

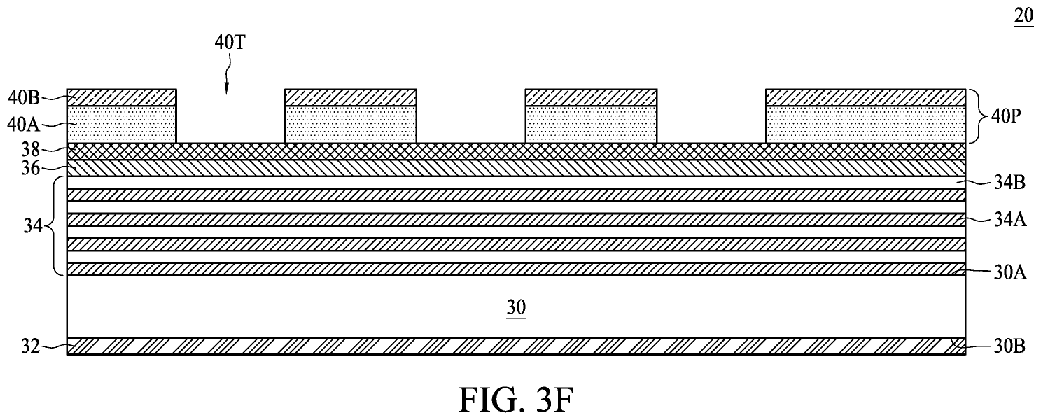

FIG. 3A, FIG. 3B, FIG. 3C, FIG. 3D, FIG. 3E and FIG. 3F are schematic views at one or more of various operations of manufacturing a mask in accordance with one or more embodiments of the present disclosure. As shown in FIG. 3A, a substrate 30 is received. In some embodiments, the substrate 30 may include a low thermal expansion material (LTEM) substrate formed from low thermal expansion material. In some embodiments, the substrate 30 may further include a material having low defect level and smooth surface. By way of examples, the material of the substrate 30 may include glass, quartz, silicon, silicon carbide, black diamond or other suitable material with low thermal expansion coefficient, low defect level and smooth surface. The low thermal expansion coefficient, low defect level and smooth surface may help alleviate image distortion due to temperature variation during fabrication or operation.

In some embodiments, a conductive layer 32 may be formed on a surface 30B e.g., a back surface of the substrate 30. The conductive layer 32 may be operable and configured to electrically couple the substrate 30 to a mask carrier 13 (as shown in FIG. 1) such as an electrostatic chuck (E-chuck). The material of the conductive layer 32 may include, but is not limited to, chromium nitride or other suitable conductive material.

As shown in FIG. 3B, a reflective multi-layered stack 34 is formed over a surface 30A e.g., a front surface of the substrate 30. The reflective multi-layered stack 34 may include a plurality of film pairs, and each film pair may include a layer 34A having a high refractive index, and another layer 34B having a low refractive index. The layer 34A having a high refractive index may be configured to scatter EUV radiation, while the layer 34B having a low refractive index may be configured to transmit EUV radiation. The layers 34A and the layers 34B arranged alternatingly are operable to provide a resonant reflectivity. In some embodiments, the film pair may include molybdenum-silicon (Mo/Si) film pairs (e.g., a layer of molybdenum and a layer of silicon stacked to each other in each film pair). In some other embodiments, the reflective multi-layered stack 34 may include molybdenum-beryllium (Mo/Be) film pairs, or other suitable materials that are configurable to highly reflect the EUV radiation.

The thickness of each layer of the reflective multi-layered stack 34 may be configured depending on the EUV wavelength and the incident angle. The thickness of the reflective multi-layered stack 34 is adjusted to achieve a maximum constructive interference of the EUV radiation reflected at each interface and a minimum absorption of the EUV radiation by the reflective multi-layered stack 34. The reflective multi-layered stack 34 may be selected such that it provides a high reflectivity to a selected radiation type/wavelength (e.g., reflectivity of between about 65% and about 75%). In some embodiments, the number of the film pairs is between 20 and 80, however, any number of film pairs is possible. In some embodiment, the reflective multi-layered stack 34 includes 40 pairs of layer of Mo/Si or Mo—Be. Each Mo/Si film pair or Mo/Be film pair has a thickness ranging from about 5 nm to about 7 nm, with a total thickness of about 300 nm. For example, the thickness of the layer 34A (e.g., molybdenum) may be about 3 nm, and the thickness of the layer 34B (e.g., silicon) may be about 4 nm.

The reflective multi-layered stack 34 may be formed over the substrate 30 by various techniques such as ion beam deposition or DC magnetron sputtering. Ion beam deposition may help to reduce perturbation and defects in the surface of the reflective multi-layered stack 34 because the deposition conditions usually may be optimized to smooth over any defect on the substrate 30. DC magnetron sputtering may help to enhance the conformity of the reflective multi-layered stack 34, and thus providing better thickness uniformity.

As shown in FIG. 3C, a capping layer 36 is formed over the reflective multi-layered stack 34. In some embodiments, the capping layer 36 is immediately adjacent to the reflective multi-layered stack 34. In some embodiments, the capping layer 36 is configured to mitigate oxidation of the reflective multi-layered stack 34 during patterning and/or repairing, an optical absorber layer to be formed.

In some embodiments, the capping layer 36 may include a ruthenium (Ru) capping layer. The material of the capping layer 36 may, alternatively or additionally, include silicon oxide, amorphous carbon or other suitable materials. The capping layer 36 may be formed by various techniques such as ion beam deposition, DC magnetron sputtering, or other physical or chemical vapor deposition techniques. A low temperature deposition operation may be chosen to form the capping layer 36 to alleviate diffusion between the capping layer 36 and the reflective multi-layered stack 34.

As shown in FIG. 3C, a buffer layer 38 is formed over the capping layer 36. In some embodiments, the buffer layer 38 is immediately adjacent to the capping layer 36. In some embodiments, the buffer layer 38 is configured as an etch stop in an absorption layer patterning operation. The buffer layer 38 can protect the underlying capping layer 36 and reflective multi-layered stack 34 from being damaged during the absorption layer patterning operation treatments and during repairing the mask. In some embodiments, the material of the buffer layer 38 may include metal silicide. For example, the material of the buffer layer 38 may include, but is not limited to, molybdenum silicide (MoSi).

In some embodiments, the optical property of the buffer layer 38 and that of the capping layer 36 are selected such that the reflectivity of the reflective multi-layered stack 34 may not be affected. For example, the refractive index (n) of the buffer layer 38 is selected to be close to that of the capping layer 36; the extinction coefficient (k) is selected to be close to that of the capping layer 36. In some embodiments, the term “close to” may refer to the refractive index (n) of the buffer layer 38 is within a range of variation of less than or equal to ±20% of that the capping layer 36, such as less than or equal to ±10%, less than or equal to ±5% or less than or equal to ±1% of that of the capping layer 36. In some embodiments, the term “close to” may refer to the extinction coefficient of the buffer layer 38 is within a range of variation of less than or equal to ±100% of that the capping layer 36, such as less than or equal to ±80%, less than or equal to ±50% or less than or equal to ±10% of that of the capping layer 36. By way of example, when the capping layer 36 includes a ruthenium capping layer having a refractive index of about 0.886 and an extinction coefficient of about 0.017 to an EUV radiation of about 13.5 nm, MoSi may be selected as the material of the buffer layer 38, which has a refractive index of about 0.969 and an extinction coefficient of about 0.0043 to an EUV radiation of about 13.5 nm.

As shown in FIG. 3D, an optical absorber layer 40 is formed over the buffer layer 38. The optical absorber layer 40 is configured to absorb the electromagnetic radiation in the EUV wavelength projected on the mask. In some embodiments, the material of the optical absorber layer 40 includes tantalum-based compound. In some embodiments, the material of the optical absorber layer 40 includes tantalum-based oxide such as tantalum oxide or tantalum boron oxide, tantalum-based nitride such as tantalum nitride or tantalum boron nitride, tantalum-based oxynitride such as tantalum oxynitride or tantalum boron oxynitride, or a combination thereof. In some other embodiments, the material of the optical absorber layer 40 may include metal such as chromium, titanium or tantalum, metal oxide such as chromium oxide, metal nitride such as titanium nitride, metal alloy such as aluminum copper alloy.

The optical absorber layer 40 may be single-layered or multi-layered. In some embodiments, the optical absorber layer 40 may be a multi-layered structure including an optical absorber film 40A immediately adjacent to the buffer layer 38, and a low-reflective film 40B stacked on the optical absorber film 40A. The optical absorber film 40A is configured to absorb the electromagnetic radiation in the EUV wavelength. By way of example, the optical absorber film 40A includes a tantalum-based nitride layer such as tantalum nitride layer or tantalum boron nitride layer. The low-reflective film 40B has low reflectivity of non-EUV radiation, and is configured to reduce reflection of non-EUV-radiation, By way of example, the low-reflective film 40B includes a tantalum-based oxide layer such as tantalum oxide layer or tantalum boron oxide layer, or a tantalum-based oxynitride layer such as tantalum oxynitride layer or tantalum boron oxynitride layer. The optical absorber film 40A and the low-reflective film 40B can collectively form the optical absorber layer 40.

As shown in FIG. 3E, a hard mask layer 42 is formed over the optical absorber layer 40. The hard mask layer 42 is patterned and includes a plurality of openings 42A partially exposing the optical absorber layer 40. In some embodiments, the material of the hard mask layer 42 may include, but is not limited to, metal such as chromium (Cr). The optical absorber layer 40 is then etched through the openings 42A of the hard mask layer 42 by a first etchant to from an optical absorber pattern 40P including trenches 40T partially exposing the buffer layer 38. The first etchant can etch the optical absorber layer 40 faster than the buffer layer 38 such that the buffer layer 38 can withstand the first etchant and protect the capping layer 36 after the optical absorber layer 40 is etched through. The first etchant is such selected that the etch rate of the material of the buffer layer 38 is lower than the etch rate of the material of the optical absorber layer 40. The distinct etch selectivity helps the etch stop at the surface of the buffer layer 38, and thus the capping layer 36 may remain intact. The first etchant is such selected that it can highly react with the optical absorber layer 40 to etch the optical absorber layer 40 fast, while it almost has no reaction with the buffer layer 38. By way of example, the material of the buffer layer 38 includes molybdenum silicide (MoSi), the material of the optical absorber layer 40 includes tantalum-based compound, and the optical absorber layer 40 may be etched by an etching operation such as plasma etching using chlorine gas as the first etchant. The plasma bombardment may damage all the layers that it contacts undergone the plasma etching, but the bombardment damage is basically the same on all layers undergone the plasma etching. Thus, the damage of the buffer layer 38 can be mitigated by selecting the first etchant when etching the optical absorber layer 40. The etch selectivity of chlorine gas (first etchant) to tantalum-based compound (the optical absorber layer 40) over MoSi (the buffer layer 38) is selected to be as high as possible, for example higher than about 10, higher than about 50, higher than about 100 or even higher, such that the buffer layer 38 can withstand the first etchant during removal of the optical absorber layer 40. The capping layer 36 can be protected by the buffer layer 38 during etching the optical absorber layer 40.

As shown in FIG. 3F, the hard mask layer 42 is etched by a second etchant to remove the hard mask layer 42 from the optical absorber pattern 40P to form a mask 20. The second etchant can etch the hard mask layer 42 faster than the buffer layer 38 such that the buffer layer 38 can withstand the second etchant and protect the capping layer 36 during removal of the hard mask layer 42. The second etchant is such selected that the etch rate of the material of the buffer layer 38 is lower than the etch rate of the material of the hard mask layer 42. The distinct etch selectivity helps the etch stop at the surface of the buffer layer 38 and alleviates damages of the buffer layer 38 during removal of the hard mask layer 42, and thus the capping layer 36 may remain intact. The second etchant is such selected that it can highly react with the hard mask layer 42 to etch the hard mask layer 42 fast, while it almost has no reaction with the buffer layer 38. By way of example, the material of the buffer layer 38 includes molybdenum silicide (MoSi), the material of the hard mask layer 42 includes chromium, and the hard mask layer 42 may be etched by an etching operation such as plasma etching using a mixture of chlorine gas and oxygen gas as the second etchant. The plasma bombardment may damage all the layers that it contacts undergone the plasma etching, but the bombardment damage is basically the same on all layers undergone the plasma etching. Thus, the damage of the buffer layer 38 can be mitigated by selecting the second etchant when etching the hard mask layer 42. The selectivity of chlorine/oxygen gas (second etchant) to chromium (the hard mask layer 42) over MoSi (the buffer layer 38) is selected to be as high as possible, for example higher than about 10, higher than about 50, higher than about 100 or even higher, such that the buffer layer 38 can withstand the second etchant during removal of the hard mask layer 42. The capping layer 36 can be protected by the buffer layer 38 during etching the hard mask layer 42.

In some embodiments, the surface 38S of the buffer layer 38 may be substantially flat after the hard mask layer 42 is removed. Alternatively, the surface 38S of the buffer layer 38 exposed from the optical absorber pattern 40P may be a non-flat surface e.g., a recessed surface, after the hard mask layer 42 is removed

In some embodiments, undesired defects such as particles or residues of the optical absorber layer 40 may exist on the buffer layer 38, and a repair operation may be selectively performed to remove the defects. In some embodiments, the defects may be corrected or removed using irradiation such as focused ion beam irradiation. The buffer layer 38 may also be configured to protect the capping layer 36 from being damaged by sputtering or implanted ions during defect repair operation using focused ion beam irradiation, which involves bombarding the defects with ions.

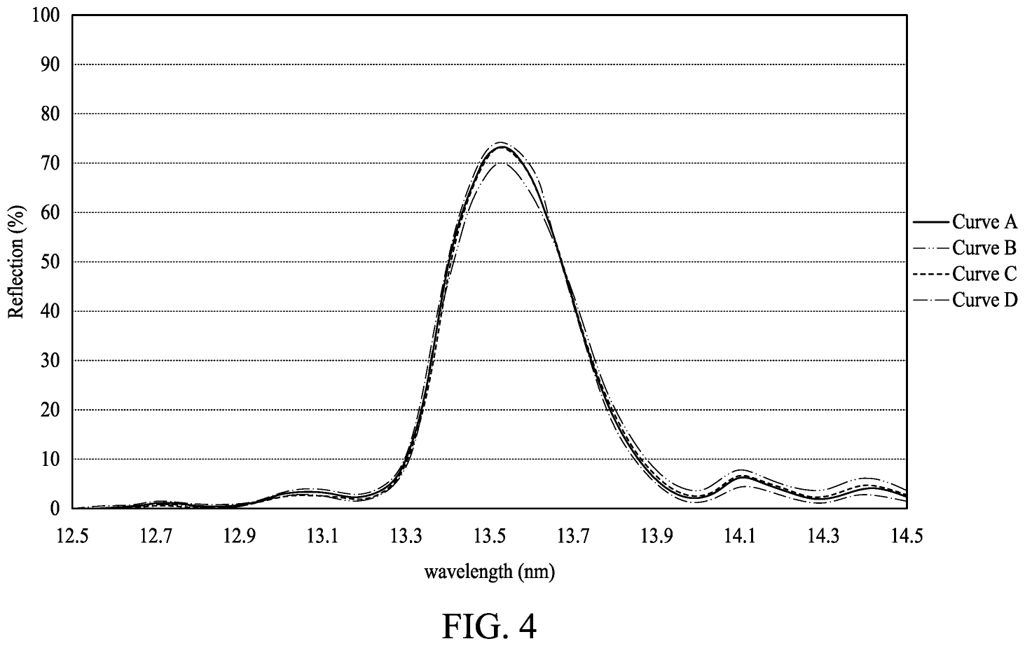

Referring to FIG. 4. FIG. 4 is a simulation result showing reflection of a stack of a capping layer and a buffer layer. In FIG. 4, curve 1 represents the reflection of a ruthenium capping layer in the absence of a MoSi buffer layer, curve 2 represents the reflection of a stack of a ruthenium capping layer/a MoSi buffer layer having a thickness of about 3.5 nm/2 nm, curve 3 represents the reflection of a stack of a ruthenium capping layer/a MoSi buffer layer having a thickness of about 2.5 nm/2 nm, and curve 4 represents the reflection of a stack of a ruthenium capping layer/a MoSi buffer layer having a thickness of about 2 nm/1.5 nm. As shown in FIG. 4, the reflection behavior of the stack of a ruthenium layer and a MoSi buffer layer is similar to that of a single ruthenium layer. The reflection of the capping layer is not substantially affected by the disposition of the buffer layer. The buffer layer, however, can protect the capping layer from being damaged during patterning the optical absorber layer, removal of the hard mask layer and/or repairing the mask.

In some embodiments, the thicknesses of the buffer layer and the capping layer can be selected according to the required reflection and protection effect. In some embodiments, the ratio of a thickness of the buffer layer to a thickness of the capping layer may range, but not be limited to, from about 0.5 to about 1. By way of example, the thickness of the capping layer may range from about 2 nm to about 5 nm, and the thickness of the buffer layer may range from about 1 nm to about 5 nm.

In some embodiments, the characteristics of the material of the buffer layer 38 is matched with that of the material of the capping layer 36 to maintain the optical performance such as the reflection of the mask. For example, the composition of metal silicide may be modified to match the characteristic of the capping layer, and to adjust the selectivity of the first etchant to the material of the optical absorber layer 40 over the buffer layer 38 and the selectivity of the second etchant to the material of the hard mask layer 42 over the material of the buffer layer 38. In some embodiments, the buffer layer 38 includes a molybdenum silicide layer having a composition of MoSiₓ, with x being about 2. However, the MoSiₓ layer can also be nonstoichiometric, i.e., x may be larger than or less than 2. In some embodiments, molybdenum silicide layer can contain other dopants, metals or alloys.

The mask for reflecting an electromagnetic radiation is not limited to the above-mentioned embodiments, and may have other different embodiments. To simplify the description and for the convenience of comparison between each of the embodiments of the present disclosure, the identical components in each of the following embodiments are marked with identical numerals. For making it easier to compare the difference between the embodiments, the following description will detail the dissimilarities among different embodiments and the identical features will not be redundantly described.

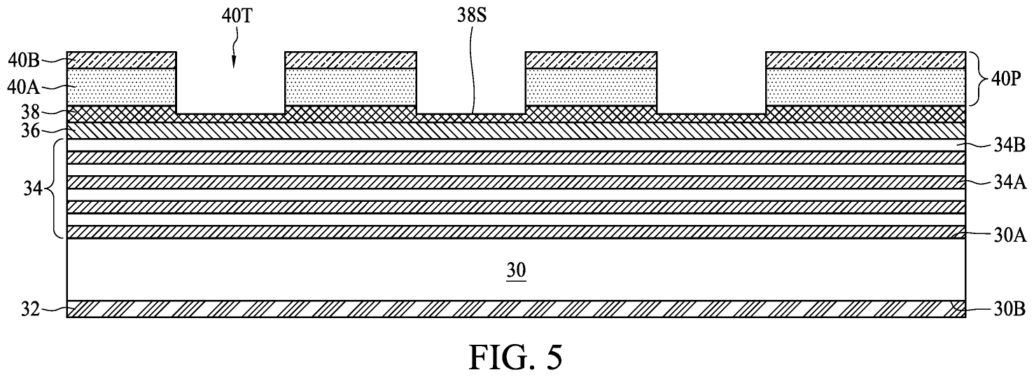

Refer to FIG. 5. FIG. 5 is a schematic view diagram illustrating a mask, in accordance with some embodiments of the present disclosure. As shown in FIG. 5, the surface 38S of the buffer layer 38 may not be flat. For example, the buffer layer 38 exposed from the optical absorber pattern 40P may be slightly etched during patterning the optical absorber layer 40 and removal of the hard mask layer 42, and the surface 38S exposed from the optical absorber pattern 40P may be recessed from the other portion of the buffer layer 38 covered with the optical absorber pattern 40P.

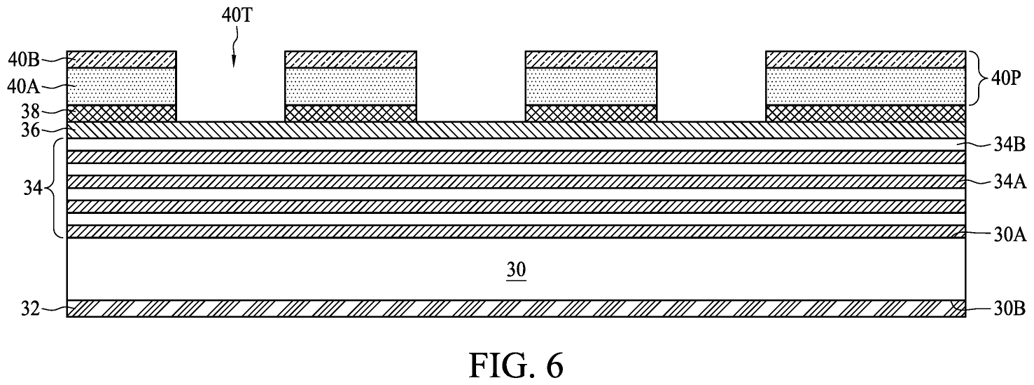

Refer to FIG. 6. FIG. 6 is a schematic view diagram illustrating a mask, in accordance with some embodiments of the present disclosure. As shown in FIG. 6, the buffer layer 38 exposed from the optical absorber pattern 40P may be removed after the patterning the optical absorber layer 40 and removal of the hard mask layer 42.

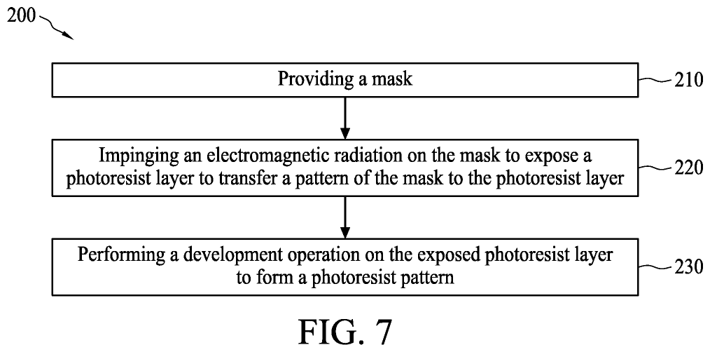

Refer to FIG. 7. FIG. 7 is a flow chart illustrating a method of patterning a layer using a mask, in accordance with various aspects of one or more embodiments of the present disclosure. The method 200 begins with operation 210 in which a mask is provided. Details of the mask are illustrated in the above embodiments, and are not redundantly described. The method 200 proceeds with operation 220 in which an electromagnetic radiation is impinged on the mask to expose a photoresist layer to transfer a pattern of the mask to the photoresist layer. The electromagnetic radiation may include, but is not limited to, an EUV radiation. The method 200 proceeds with operation 230 in which a development operation is performed on the exposed photoresist layer to form a photoresist pattern.

The method 200 is merely an example, and is not intended to limit the present disclosure beyond what is explicitly recited in the claims. Additional operations can be provided before, during, and after the method 100, and some operations described can be replaced, eliminated, or moved around for additional embodiments of the method.

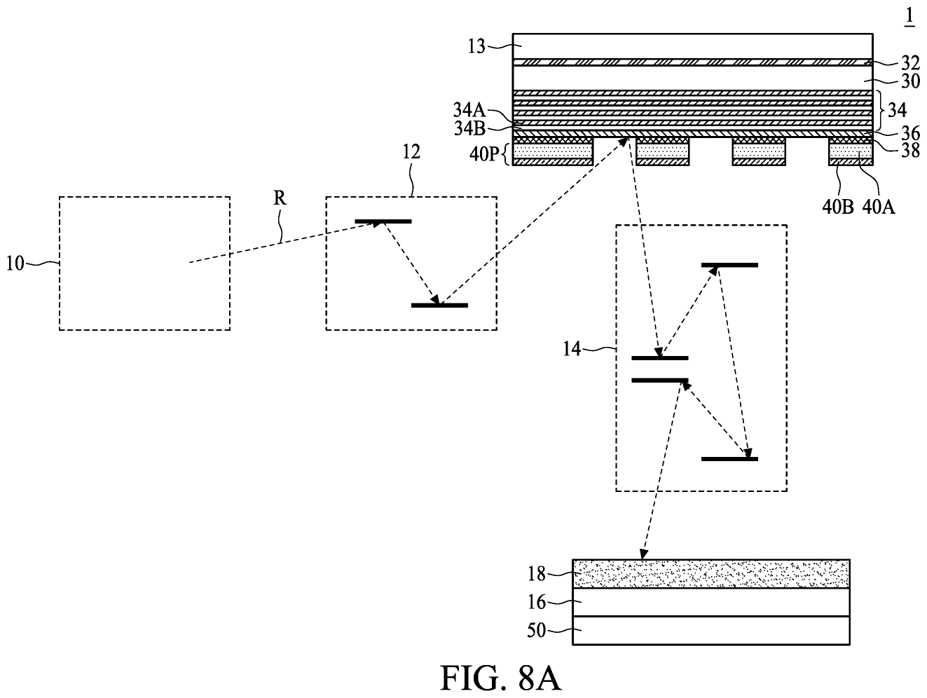

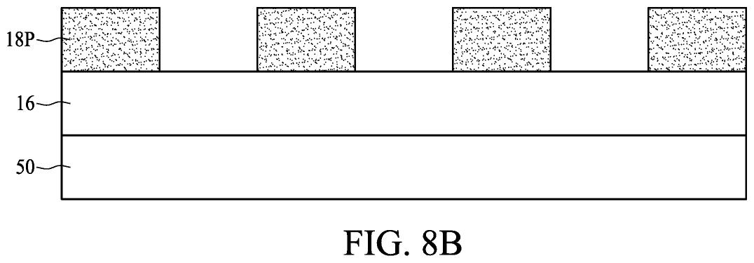

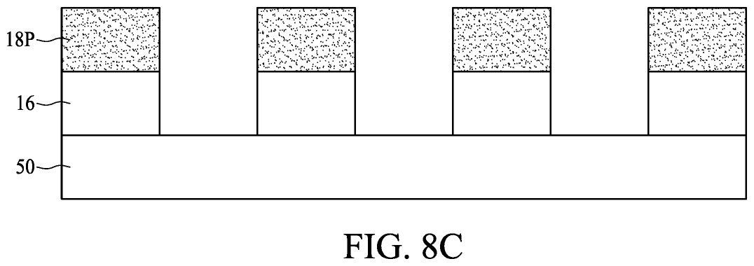

FIG. 8A, FIG. 8B and FIG. 8C are schematic views at one or more of various operations of patterning a layer using a mask in accordance with one or more embodiments of the present disclosure. As shown in FIG. 8A, a mask is provided. The mask include a reflective multi-layered stack 34, a metal capping layer 36 over the reflective multi-layered stack 34, a metal silicide buffer layer 38 over the metal capping layer 36, and an optical absorber pattern 40P over the metal silicide buffer layer 38. In some embodiments, the electromagnetic radiation generation apparatus 1 as shown in FIG. 1 may be used to impinge an electromagnetic radiation R on the mask to expose a photoresist layer 18 to transfer a pattern of the mask to the photoresist layer 18. The electromagnetic radiation R may include, but is not limited to, an EUV radiation

As shown in FIG. 8B, the exposed photoresist layer 18 may be developed, for example, by stripping to form a photoresist pattern 18P. As shown in FIG. 8C, an underlying layer 16 may be patterned using the photoresist pattern 18P as an etching mask. The underlying layer 16 may be etched by dry etch, wet etch or a combination thereof. The underlying layer 16 may include a semiconductor layer, a conductive layer such as metal, a dielectric layer or a stacked layer thereof. In some embodiments, the photoresist pattern 18P may be removed after the underlying layer 16 is patterned.

In some embodiments of the present disclosure, a mask for reflecting an electromagnetic radiation and fabrication method thereof are provided. The mask utilizes a buffer layer to cover a capping layer. The buffer layer and the capping layer are similar in optical characteristics but different in etch rate with respect to an etchant for patterning overlying optical absorber layer. The etch rate of the buffer layer is lower than the etch rate of the optical absorber layer with respect to the same etchant when patterning the optical absorber layer. The buffer layer can protect the capping layer and underlying reflective multi-layered stack, while the optical performance of the mask may be maintained. The mask with good optical performance can increase the pattern accuracy transferred to the photoresist layer, and thus the underlying layer can be accurately patterned.

In some embodiments, a mask for reflecting an electromagnetic radiation includes a substrate, a reflective multi-layered stack over a surface of the substrate, a metal capping layer over the reflective multi-layered stack, a metal silicide buffer layer over the metal capping layer, and an optical absorber pattern over the metal silicide buffer layer.

In some embodiments, a method of manufacturing a mask includes following operations. A reflective multi-layered stack, a capping layer, a buffer layer and an optical absorber layer are formed over a substrate. A hard mask layer is formed over the optical absorber layer, wherein the hard mask layer includes a plurality of openings. The optical absorber layer is etched through the openings of the hard mask layer by a first etchant to from an optical absorber pattern exposing the buffer layer, wherein a selectivity of the first etchant to a material of the optical absorber layer over a material of the buffer layer is higher than a selectivity of the first etchant to the material of the optical absorber layer over a material of the capping layer.

In some embodiments, a method of patterning a layer includes following operations. A mask is provided. The mask includes a reflective multi-layered stack, a metal capping layer over the reflective multi-layered stack, a metal silicide buffer layer over the metal capping layer, and an optical absorber pattern over the metal silicide buffer layer. An electromagnetic radiation is impinged on the mask to expose a photoresist layer to transfer a pattern of the mask to the photoresist layer. A development operation is performed on the exposed photoresist layer to form a photoresist pattern.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A mask for reflecting an electromagnetic radiation, comprising:
a substrate;
a reflective multi-layered stack over a surface of the substrate;
a metal capping layer over the reflective multi-layered stack;
a metal silicide buffer layer over the metal capping layer; and
an optical absorber pattern over the metal silicide buffer layer.

2. The mask of claim 1, wherein a material of the metal capping layer comprises ruthenium (Ru).

3. The mask of claim 1, wherein a material of the optical absorber pattern comprises tantalum-based compound.

4. The mask of claim 1, wherein the optical absorber pattern comprises an optical absorber film, and a low-reflective film stacked on the optical absorber film.

5. The mask of claim 1, wherein a material of the metal silicide buffer layer comprises molybdenum silicide (MoSi).

6. The mask of claim 1, wherein a ratio of a thickness of the metal silicide buffer layer to a thickness of the metal capping layer ranges from about 0.5 to about 1.

7. The mask of claim 1, wherein a refractive index of a material of the metal silicide buffer layer is close to a refractive index of a material of the metal capping layer.

8. The mask of claim 1, wherein an extinction coefficient of a material of the metal silicide buffer layer is close to an extinction coefficient of a material of the metal silicide capping layer.

9. The mask of claim 1, wherein an etch selectivity of a material of the optical absorber pattern over a material of the metal silicide buffer layer with respect to a same etchant is higher than about 10.

10. A method of manufacturing a mask, comprising:
forming a reflective multi-layered stack, a capping layer, a buffer layer and an optical absorber layer over a substrate;
forming a hard mask layer over the optical absorber layer, wherein the hard mask layer includes a plurality of openings; and
etching the optical absorber layer through the openings of the hard mask layer by a first etchant to from an optical absorber pattern exposing the buffer layer, wherein an etch rate of a material of the buffer layer is lower than an etch rate of a material of the optical absorber pattern with respect to the first etchant.

11. The method of claim 10, wherein an etch selectivity of the material of the optical absorber layer over the material of the buffer layer with respect to the first etchant is higher than about 10.

12. The method of claim 11, further comprising:
etching the hard mask layer by a second etchant to remove the hard mask layer from the optical absorber pattern,
wherein an etch rate of the material of the buffer layer is lower than an etch rate of a material of the hard mask layer with respect to the second etchant.

13. The method of claim 12, wherein an etch selectivity of the material of the hard mask layer over the material of the buffer layer with respect to the second etchant is higher than about 10.

14. The method of claim 10, wherein the material of the buffer layer comprises metal silicide, the material of the optical absorber layer comprises tantalum-based compound, and a material of the hard mask layer comprises metal.

15. The method of claim 14, wherein the material of the buffer layer comprises molybdenum silicide (MoSi).

16. The method of claim 14, wherein the material of the hard mask layer comprises chromium.

17. The method of claim 10, further comprising matching characteristics of the material of the buffer layer with that of a material of the capping layer.

18. A method of patterning a layer, comprising:
providing a mask comprising:
a reflective multi-layered stack;
a metal capping layer over the reflective multi-layered stack;
a metal silicide buffer layer over the metal capping layer; and
an optical absorber pattern over the metal silicide buffer layer;
impinging an electromagnetic radiation on the mask to expose a photoresist layer to transfer a pattern of the mask to the photoresist layer; and
performing a development operation on the exposed photoresist layer to form a photoresist pattern.

19. The method of claim 18, wherein the electromagnetic radiation comprises an EUV radiation.

20. The method of claim 19, further comprising patterning an underlying layer using the photoresist pattern as an etching mask.
